(19) United States
(12) Patent Application Publication
(10) Pub. No.: US 2018/0157136 A1
(43) Pub. Date: Jun. 7, 2018

(54) AN ARRAY SUBSTRATE FOR IMPROVING HORIZONTAL BRIGHT AND DARK LINES, AND LIQUID CYSTAL DISPLAY PANEL

(71) Applicant: Shenzhen China Star Optoelectronics Technology Co. Ltd., Shenzhen (CN)

(72) Inventor: Huan LIU, Shenzhen (CN)

(73) Assignee: Shenzhen China Star Optoelectronics Technology Co. Ltd., Shenzhen (CN)

(21) Appl. No.: 14/897,727

(22) PCT Filed: Oct. 30, 2015
(86) PCT No.: PCT/CN2015/093320

§ 371 Date: Feb. 14, 2018

(30) Foreign Application Priority Data
Oct. 16, 2015 (CN) 201510675744.8

(51) Int. Cl. G02F 1/1362; H01L 27/12

(52) U.S. Cl. CPC G02F 1/136286; G09G 3/3614; H01L 27/124

(57) ABSTRACT

Disclosed is an array substrate for eliminating horizontal bright and dark lines, and a liquid crystal display panel for the same. The array substrate comprises a plurality of pixels arranged in a matrix form; grid lines disposed between rows of pixels; and data lines for providing driving signals to said pixels, wherein pixels in a same row are connected alternately to grid lines located at two sides thereof, so that horizontal bright and dark lines are eliminated when two-dot polarity inversion of the data line is used. The horizontal bright and dark lines can be eliminated when two-dot polarity inversion of the data line is used.

### CROSS-REFERENCE TO RELATED APPLICATIONS

The present application claims the priority of Chinese patent application 201510675744.8, entitled “An array substrate for improving horizontal bright and dark lines, and liquid crystal display panel” and filed on Oct. 16, 2015, the entirety of which is incorporated herein by reference.

### FIELD OF THE INVENTION

The present disclosure relates to the technical field of liquid crystal display control, and in particular, to an array substrate for improving horizontal bright and dark lines and a liquid crystal display panel.

### BACKGROUND OF THE INVENTION

In prior art, it is provided that a data line is disposed under a keel of a pixel. Since the keel of a pixel itself is dark and the data line itself is made of an opaque metal, disposing the data line under the keel of a pixel can increase an aperture ratio of the pixel. Meanwhile, as the data line is disposed in a center of the pixel, it is unnecessary to arrange a black matrix layer in a vertical direction of the pixel to shade the data line. Therefore, this pixel design can obviously increase the aperture ratio of the pixel. This kind of pixel is termed a CDL pixel, i.e., a center data line pixel.

However, a coupling capacity between the data line of the CDL pixel and an ITO pixel electrode is large, such that change of voltage on the data line can lead to change of voltage on the pixel electrode. If a polarity inversion mode of data line column inversion is used, serious vertical crosstalk among pixels would appear.

Vertical crosstalk can be decreased, if a polarity inversion mode of two-dot polarity inversion of the data line or single-dot polarity inversion of the data line is used. This is because these two polarity inversion modes enable an upward coupling effect between the pixel electrodes and the data line to counteract a downward coupling effect between the pixel electrodes and the data line. However, the single-dot polarity inversion would lead to excessive current on a panel and excessive temperature of an IC, which can easily cause damage to the IC. The current under the two-dot polarity inversion is smaller than the current under the single-dot polarity inversion, but horizontal bright and dark lines would be generated on the panel, in case the pixels are designed in accordance with the two-dot polarity inversion.

### SUMMARY OF THE INVENTION

To solve the aforementioned problem, the present disclosure provides an array substrate for eliminating horizontal bright and dark lines, and a liquid crystal display panel for the same.

According to one embodiment of the present disclosure, an array substrate for eliminating horizontal bright and dark lines is provided, comprising:

a plurality of pixels arranged in a matrix form;

grid lines disposed between pixel rows; and

data lines for providing driving signals to said pixels,

wherein pixels in a same row are connected to the grid lines located at two sides thereof alternately, so that horizontal bright and dark lines can be eliminated when two-dot polarity inversion of the data line is used.

According to one embodiment of the present disclosure, the data line is disposed at one side of a column of pixels or under a keel of the column of pixels.

According to one embodiment of the present disclosure, a grid line is disposed outside of a first row of pixels on said array substrate for controlling half of the first row of pixels.

According to one embodiment of the present disclosure, a grid line is disposed outside of a last row of pixels on said array substrate for controlling half of the last row of pixels.

According to one embodiment of the present disclosure, in said array substrate, two pixels having a same polarity and being adjacent in a longitudinal direction are regarded as a group. Pixel groups with different polarities in a same column are alternately arranged, and a polarity arrangement of two adjacent columns of pixels is regarded as a unit and recurs on said array substrate, wherein in a unit, after the polarities of one column of pixels are inversed as a whole and then the column of pixels with inversed polarities moves one pixel position in the longitudinal direction, a polarity arrangement of the other column of pixels in said unit is obtained.

According to another aspect of the present disclosure, a liquid crystal display panel for eliminating horizontal bright and dark lines is further provided, which comprises an array substrate. The array substrate comprises:

a plurality of pixels arranged in a matrix form;

grid lines disposed between pixel rows; and

data lines for providing driving signals to said pixels,

wherein pixels in a same row are connected to the grid lines located at two sides thereof alternately, so that horizontal bright and dark lines can be eliminated when two-dot polarity inversion of the data line is used.

According to one embodiment of the present disclosure, the data line is disposed at one side of a column of pixels or under a keel of the column of pixels.

According to one embodiment of the present disclosure, a grid line is disposed outside of a first row of pixels on said array substrate for controlling half of the first row of pixels.

According to one embodiment of the present disclosure, a grid line is disposed outside of a last row of pixels on said array substrate for controlling half of the last row of pixels.

According to one embodiment of the present disclosure, in said array substrate, two pixels having a same polarity and being adjacent in a longitudinal direction are regarded as a group. Pixel groups with different polarities in a same column are alternately arranged, and a polarity arrangement of two adjacent columns of pixels is regarded as a unit and recurs on said array substrate, wherein in a unit, after the polarities of one column of pixels are inversed as a whole and then the column of pixels with inversed polarities moves one pixel position in the longitudinal direction, a polarity arrangement of the other column of pixels in said unit is obtained.

In the present disclosure, the connecting manner between the pixels and the grid lines is changed, so that when two-dot polarity inversion of the data line is used, the horizontal bright and dark lines on the display panel can be eliminated.

Other features and advantages of the present disclosure will be further explained in the following description, and will partly become self-evident therefrom, or be understood through the implementation of the present disclosure. The objectives and advantages of the present disclosure will be achieved through the structures specifically pointed out in the description, claims, and the accompanying drawings.

### BRIEF DESCRIPTION OF THE DRAWINGS

The drawings are provided for further understanding of the present disclosure, and constitute one part of the description. They serve to explain the present disclosure in conjunction with the embodiments, rather than to limit the present disclosure in any manner. In the drawings:

FIG. 1 schematically shows a CDL pixel structure in the prior art;

FIG. 2 schematically shows generation of bright and dark lines on a panel with a CDL pixel structure under two-dot polarity inversion of a data line;

FIG. 3 schematically shows ideal voltages of the data line and actual voltages of the data line when the data line charges a pixel;

FIG. 4 schematically shows the structure of an array substrate according to one embodiment of the present disclosure;

FIG. 5a schematically shows wiring of a first grid line on the array substrate shown in FIG. 4; and

FIG. 5b schematically shows wiring of a last grid line on the array substrate shown in FIG. 4.

### DETAILED DESCRIPTION OF THE EMBODIMENTS

The present disclosure will be explained in detail below with reference to the accompanying drawings, so that one can better understand the objective, the technical solutions, and the advantages of the present disclosure.

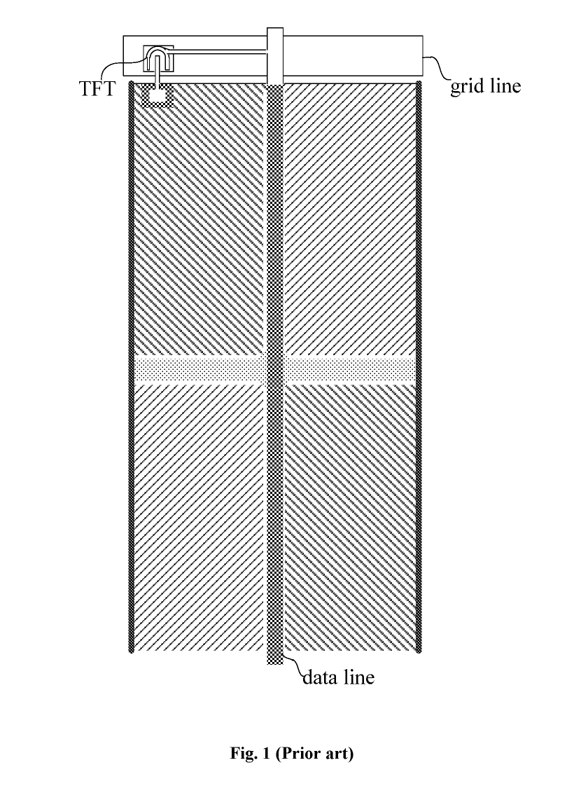

FIG. 1 schematically shows a CDL pixel structure in the prior art. It is known from FIG. 1 that disposing a data line under a keel of a pixel can increase an aperture ratio of the pixel. However, a coupling capacity between the data line of the CDL pixel and an ITO pixel electrode is large, such that change of voltage on the data line can lead to change of voltage on the pixel electrode. If a polarity inversion mode of data line column inversion is used, serious vertical crosstalk among pixels would appear.

Vertical crosstalk can be decreased, if a polarity inversion mode of two-dot polarity inversion or single-dot polarity inversion is used. This is because these two polarity inversion modes enable an upward coupling effect between the pixel electrodes and the data line to counteract a downward coupling effect between the pixel electrodes and the data line. However, the single-dot polarity inversion would lead to excessive current on a panel and excessive temperature of an IC, which can easily cause damage to the IC. A current under the two-dot polarity inversion is smaller than the current under the single-dot polarity inversion, but horizontal bright and dark lines would be generated on the panel if the pixels are designed in accordance with the two-dot polarity inversion.

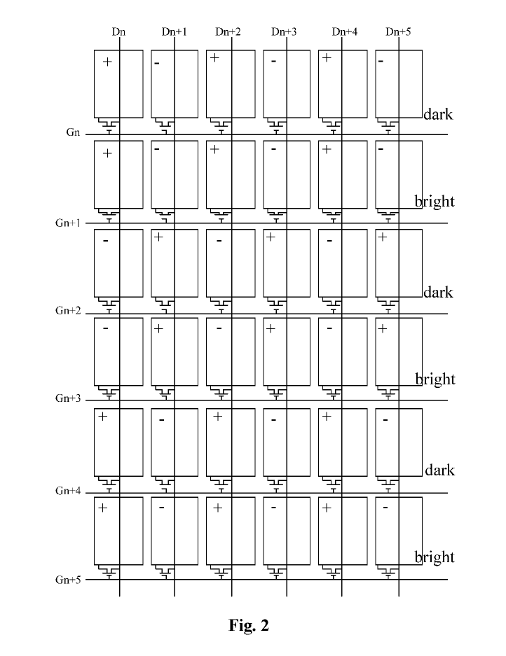

FIG. 2 schematically shows generation of horizontal bright and dark lines on the panel with a CDL pixel structure under the two-dot polarity inversion. As shown in FIG. 2, the polarities of two adjacent pixels on each data line column are inversed once, and the polarities of all data lines are inversed at the same time, so that the number of the data lines from positive polarity to negative polarity, equals the number of the data lines from negative polarity to positive polarity. As a result, the coupling effects between the common electrodes and the data lines counteract each other. In panel design, one grid line controls pixels located in a same row generally, or in other words, controlled pixels are disposed at a same side of a controlling grid line, and bright and dark lines would easily occur under the two-dot polarity inversion of the data line.

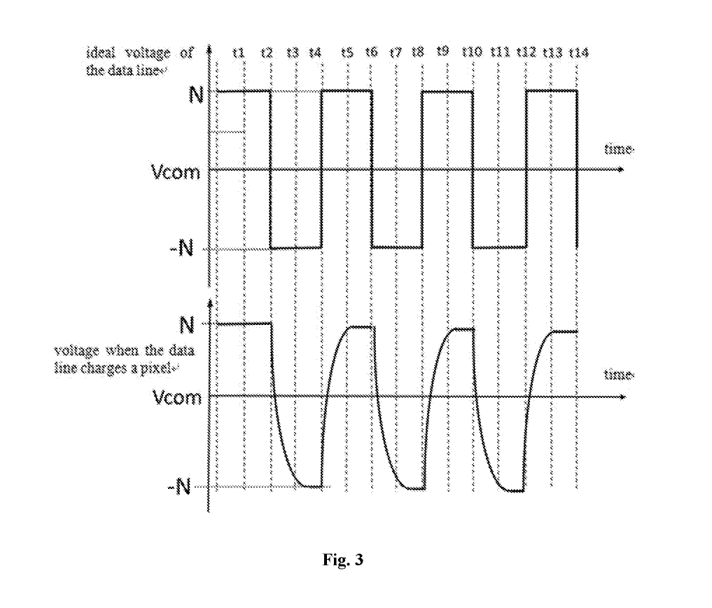

The pixel rows corresponding to grid lines Gn+1 and Gn+2 will be used as examples to illustrate the reasons for generation of horizontal bright and dark lines in the following. For the pixel driven by data line Dn, when grid line Gn+1 is activated, since the polarity of the pixel in the row Gn is positive, the polarity of the pixel in the row Gn+1 is also positive. Thus the voltage of the data line does not change, and the voltage when the data line charges the pixel is shown from t5 to t6 in FIG. 3. The charge efficiency of the pixel in row Gn+1 is high. Likewise, the charge efficiencies of pixels controlled by grid line Gn+1 and driven by data lines Dn+1 to Dn+5 are high, so that a bright line is generated on the row Gn+1.

Then, grid line Gn+2 is activated, and the polarity of the data line is inversed at this time. Due to an RC signal delay effect of the data line, for the pixel driven by data line Dn, the actual voltage of the data line charging the pixel is shown from t6 to t7 in FIG. 3. Since the actual charge voltage is low, the charge efficiency of pixel in row Gn+2 is low. Likewise, the charge efficiencies of pixels controlled by grid line Gn+2 and driven by data lines Dn+1 to Dn+5 are low, so that a dark line is generated on pixels of row Gn+2. Likewise, for pixels controlled by other grid lines, it is always the case that the charge efficiencies of one of two adjacent rows of pixels are high while the charge efficiencies of the other of said two adjacent rows of pixels are low. Thus, bright and dark lines would be generated as shown in FIG. 2.

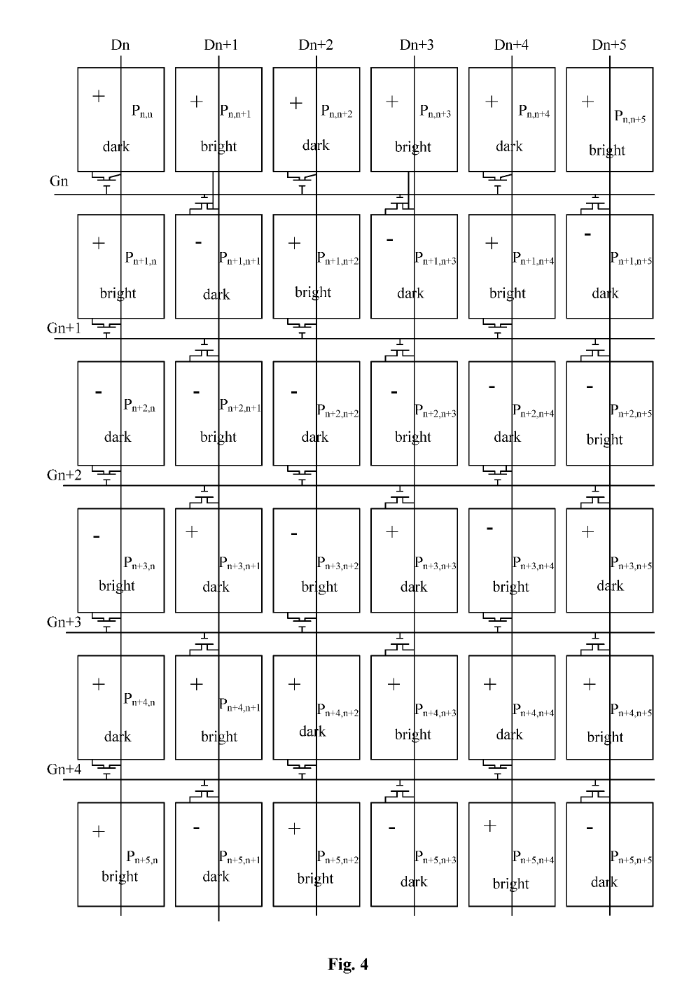

Therefore, the present disclosure provides an array substrate, in which pixels in a row are connected to grid lines located thereabove and therebelow alternately, so that pixels of each row on the substrate are bright and dark in turn. Thus the horizontal bright and dark lines are eliminated, and further the brightness on the panel on the whole is homogenous. FIG. 4 schematically shows the structure of the array substrate according to one embodiment of the present disclosure, and the present disclosure will be illustrated in detail in reference to FIG. 4.

This array substrate comprises a plurality of pixels arranged in a matrix form and grid lines disposed between rows of pixels, and further comprises data lines for providing driving signals to the pixels, wherein pixels in a same row are connected to the grid lines located at both sides thereof alternately, so that horizontal bright and dark lines can be eliminated when a two-dot inversion of data line is used.

As shown in FIG. 4, grid lines are disposed at both sides of each row of pixels, and pixels in the same row are connected to the grid lines located at both sides thereof alternately. In other words, one of two adjacent pixels in the same row is connected to the grid line located at one side thereof, while the other of said two adjacent pixels in the same row is connected to the grid line located at the other side thereof, i.e., the grid lines are connected to the pixels in an alternate manner. Meanwhile, the grid line disposed between two adjacent rows of pixels is connected alternately to said two adjacent rows of pixels, so as to achieve controlling of some pixels located in both of said two adjacent rows.

Under the wiring shown in FIG. 4, when two-dot polarity inversion of the data line is used and polarities of all data lines are inversed at the same time, upward and downward coupling effects between the pixel electrodes and the data lines counteract each other, thereby reducing vertical crosstalk on the display panel. In addition, under the circumstance that data lines charge the pixels shown in FIG. 3, horizontal bright and dark lines on the display panel can be eliminated when the wiring shown in FIG. 4 is used.

Specifically, the pixels driven by data lines Dn and Dn+1 shown in FIG. 4 are used as examples for explanation, wherein two pixels having a same polarity and being adjacent in a longitudinal direction are regarded as a group, and the polarities of such a group of pixels are the same. When the grid line Gn outputs a scanning signal and the data lines Dn and Dn+1 output driving signals, the actual charge voltage of pixel P_{n,n} is from t4 to t5 shown in FIG. 3, and the actual charge voltage of pixel P_{n+1, n+1} is from t2 to t3 shown in FIG. 3. The charge efficiencies of pixel P_{n, n} and pixel P_{n+1, n+1} are low, so that they are dark. When the grid line Gn+1 outputs a scanning signal and the polarities of the driving signals output by the data lines Dn and Dn+1 are unchanged, the actual charge voltage of pixel P_{n+1, n} is from t5 to t6 shown in FIG. 3, and the actual charge voltage of pixel P_{n+1, n+2} is from t3 to t4 shown in FIG. 3. The charge efficiencies of pixel P_{n+1, n} and pixel P_{n+1, n+2} are high, so that they are bright.

So, for adjacent pixels P_{n+1, n} and P_{n+1, n+1} in the same row, pixel P_{n+1, n} is bright, while pixel P_{n+1, n+1} is dark. Other pixels in the same row are bright or dark alternately. The circumstance that pixels in the same row are all bright or dark would not appear, and thus horizontal bright or dark lines would not be generated. Likewise, for pixels in other rows, the circumstance that pixels in the same row are all bright or dark would not appear, either, and thus, horizontal bright and dark lines on the display panel can be eliminated.

In addition, both pixel P_{n+1, n} and pixel P_{n+2, n+1} controlled by grid line Gn+1 are bright, and other pixels controlled by grid line Gn+1 are also bright. And likewise, pixels controlled by grid lines Gn+3 and Gn+5 and are also bright. Both pixel P_{n, n} and pixel P_{n+1, n+1} controlled by grid line Gn are dark, and other pixels controlled by grid line Gn are also dark. And likewise, pixels controlled by grid lines Gn+2 and Gn+4 and are also dark.

Pixel P_{n+1, n} and pixel P_{n+2, n+1} controlled by grid line Gn+1 are both bright in a same picture. It means when pixel P_{n+2, n} and pixel P_{n+3, n+1} are displayed, the polarities of data lines Dn and Dn+1 would be inversed, while when pixel P_{n+1, n} and pixel P_{n+2, n+1} are displayed, neither the polarity of data line Dn nor that of data line Dn+1 will be inversed.

To achieve the aforementioned display effects, the present disclosure further provides a new pixel polarity arrangement manner. As shown in FIG. 4, on the array substrate, two pixels having a same polarity and being adjacent in a longitudinal direction are regarded as a group. Pixel groups with different polarities in a same column are alternated, and a polarity arrangement of two adjacent columns of pixels is regarded as a unit and recurs. The polarities of a column of pixels in a unit are obtained by inversing the polarities an adjacent column of pixels as a whole in said unit and then moving said adjacent column of pixels with inversed polarities one pixel position in the longitudinal direction. That is, in the traditional pixel polarity arrangement manner shown in FIG. 2, the pixel polarity arrangement manner of the column of pixels driven by data line Dn is the same as the pixel polarity arrangement manner of the columns of pixels, which are spaced by an odd number of columns of pixels from the column of pixels driven by data line Dn; while the pixel polarity arrangement manner of the column of pixels driven by data line Dn+1 can be moved one row downward as a whole to obtain the pixel polarity arrangement manner of the columns of pixels, which are spaced by an odd number of columns of pixels from the column of pixels driven by data line Dn+1.

FIG. 4 schematically shows an array substrate using a CDL structure, i.e., the data line is disposed under the keel of the pixels. However, in the present disclosure, the data line is not disposed on the pixels but at one side of the column of pixels, whereby horizontal bright and dark lines can also be eliminated from the substrate.

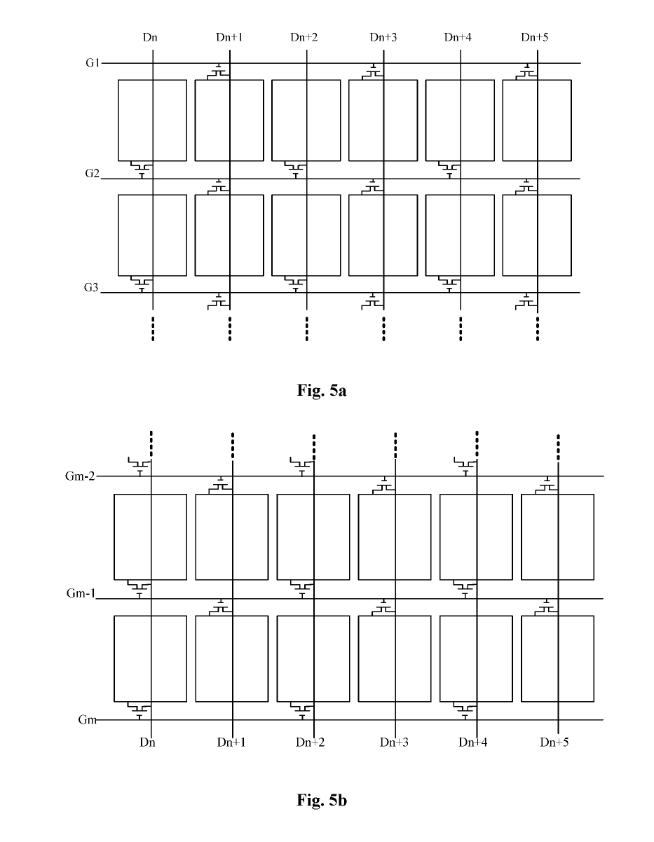

In addition, since the pixels in a row are connected to the grid lines located thereabove and therebelow alternately in the present disclosure, a first grid line on the substrate only connects half of a first row of pixels, as shown in FIG. 5a. Likewise, a last grid line on the substrate only connects half of a last row of pixels, as shown in FIG. 5b. In this way, the present disclosure has one more grid line on the whole than the traditional way as shown in FIG. 2.

According to another aspect of the present disclosure, a liquid crystal display panel is further provided. The liquid crystal display panel comprises the aforementioned array substrate. The array substrate comprises: a plurality of pixels arranged in a matrix form; grid lines disposed between rows of pixels; and data lines for providing driving signals to said pixels, wherein, pixels in a same row are connected to the grid lines located thereabove and therebelow alternately, so that horizontal bright and dark lines can be eliminated when two-dot polarity inversion of the data line is used.

In one embodiment of the present disclosure, the data line on the array substrate is disposed at one side of the column of pixels or under the keel of the columns of pixels. In one embodiment of the present disclosure, one grid line is disposed outside of the first row of pixels on the substrate for controlling half the number of the first row of pixels. In one embodiment of the present disclosure, one grid line is disposed outside of the last row of pixels on the substrate for controlling half of the last row of pixels.

In one embodiment of the present disclosure, on the array substrate, two pixels having the same polarity and being adjacent in the longitudinal direction are regarded as a group, and pixel groups with different polarities in the same column are alternately arranged. The polarity arrangement of two adjacent columns of pixels is regarded as a unit and recurs on said array substrate, wherein in a unit, after the polarities of one column of pixels are inversed as a whole and then the column of pixels with inversed polarities moves one pixel position in the longitudinal direction, the polarity arrangement of the other column of pixels in said unit is obtained.

Although the embodiments are disclosed as above, the embodiments are described only for better understanding, rather than restricting the present disclosure. Anyone skilled in the art can make amendments to the implementing forms or details without departing from the spirit and scope of the present disclosure. The scope of the present disclosure should be subject to the scope defined in the claims.

1. An array substrate for eliminating horizontal bright and dark lines, comprising:
a plurality of pixels arranged in a matrix form;
grid lines disposed between rows of pixels; and
data lines for providing driving signals to said pixels,
wherein pixels in a same row are connected alternatively to the grid lines located at two sides thereof, so that horizontal bright and dark lines are eliminated when two-dot polarity inversion of the data line is used.

2. The array substrate according to claim 1, wherein the data line is disposed at one side of a column of pixels or under a keel of the column of pixels.

3. The array substrate according to claim 1, wherein a grid line is disposed outside of a first row of pixels on the array substrate, for controlling half of the first row of pixels.

4. The array substrate according to claim 3, wherein a grid line is disposed outside of a last row of pixels on the array substrate, for controlling half of the last row of pixels.

5. The array substrate according to claim 4, wherein on the array substrate, two pixels having a same polarity and being adjacent in a longitudinal direction are regarded as a group,
wherein pixel groups with different polarities in a same column are alternately arranged, and a polarity arrangement of two adjacent columns of pixels is regarded as a unit and recurs on said array substrate, and
wherein in a unit, after polarities of one column of pixels are inversed as a whole and then the column of pixels with inversed polarities moves one pixel position in the longitudinal direction, a polarity arrangement of the other column of pixels in said unit is obtained.

6. The array substrate according to claim 2, wherein a grid line is disposed outside of a first row of pixels on the array substrate, for controlling half of the first row of pixels.

7. The array substrate according to claim 6, wherein a grid line is disposed outside of a last row of pixels on the array substrate, for controlling half of the last row of pixels.

8. The array substrate according to claim 7, wherein on the array substrate, two pixels having a same polarity and being adjacent in a longitudinal direction are regarded as a group,
wherein pixel groups with different polarities in a same column are alternately arranged, and a polarity arrangement of two adjacent columns of pixels is regarded as a unit and recurs on said array substrate, and
wherein in a unit, after polarities of one column of pixels are inversed as a whole and then the column of pixels with inversed polarities moves one pixel position in the longitudinal direction, a polarity arrangement of the other column of pixels in said unit is obtained.

9. A liquid crystal display device for eliminating horizontal bright and dark lines, comprising an array substrate, which includes:
a plurality of pixels arranged in a matrix form;
grid lines disposed between rows of pixels; and
data lines for providing driving signals to said pixels,
wherein pixels in a same row are connected alternately to grid lines located at two sides thereof, so that horizontal bright and dark lines are eliminated when two-dot polarity inversion of the data line is used.

10. The liquid crystal display device according to claim 9, wherein the data line is disposed at one side of a column of pixels or under a keel of the columns of pixels.

11. The liquid crystal display device according to claim 9, wherein a grid line is disposed outside of a first row of pixels on the array substrate, for controlling half of the first row of pixels.

12. The liquid crystal display device according to claim 11, wherein a grid line is disposed outside of a last row of pixels on the array substrate, for controlling half of the last row of pixels.

13. The liquid crystal display device according to claim 12, wherein on the array substrate, two pixels having a same polarity and being adjacent in a longitudinal direction are regarded as a group,
wherein pixel groups with different polarities in a same column are alternately arranged, and a polarity arrangement of two adjacent columns of pixels is regarded as a unit and recurs on said array substrate, and
wherein in a unit, after polarities of one column of pixels are inversed as a whole and then the column of pixels with inversed polarities moves one pixel position in the longitudinal direction, a polarity arrangement of the other column of pixels in said unit is obtained.

14. The liquid crystal display device according to claim 10, wherein a grid line is disposed outside of a first row of pixels on the array substrate, for controlling half of the first row of pixels.

15. The liquid crystal display device according to claim 14, wherein a grid line is disposed outside of a last row of pixels on the array substrate, for controlling half of the last row of pixels.

16. The liquid crystal display device according to claim 15, wherein on the array substrate, two pixels having a same polarity and being adjacent in a longitudinal direction are regarded as a group,
wherein pixel groups with different polarities in a same column are alternately arranged, and a polarity arrangement of two adjacent columns of pixels is regarded as a unit and recurs on said array substrate, and
wherein in a unit, after polarities of one column of pixels are inversed as a whole and then the column of pixels with inversed polarities moves one pixel position in the longitudinal direction, a polarity arrangement of the other column of pixels in said unit is obtained.
